(19) United States
(12) Patent Application Publication
(10) Pub. No.: US 2011/0155215 A1
(43) Pub. Date: Jun. 30, 2011

(54) SOLAR CELL HAVING A TWO DIMENSIONAL PHOTONIC CRYSTAL

(75) Inventors: Yen-Liang Shen, Tainan City (TW); Cheng-Hsin Chen, Changhua County (TW); Chih-Ming Lin, Hsinchu County (TW)

(73) Assignee: Du Pont Apollo Limited, Hong Kong (HK)

(21) Appl. No.: 12/979,395

(22) Filed: Dec. 28, 2010

Related U.S. Application Data
(60) Provisional application No. 61/291,415, filed on Dec. 31, 2009.

(51) Int. Cl. H01L 31/052

(52) U.S. Cl. 136/246

(57) ABSTRACT

Disclosed herein is a solar cell, which includes a substrate, a photoactive member and a two dimensional photonic crystal. The photoactive member is disposed on a surface of the substrate. The two dimensional photonic crystal is disposed on the surface of the substrate and adjacent to the photoactive member such that a light propagated from the photoactive member is reflected back to the photoactive member.

### RELATED APPLICATIONS

This application claims priority to U.S. Provisional Application Ser. No. 61/291,415, filed Dec. 31, 2009, which is herein incorporated by reference.

### BACKGROUND

1. Field of Invention

The present invention relates to a solar cell. More particularly, the present invention relates to a solar cell having a two dimensional photonic crystal.

2. Description of Related Art

Solar energy has gained many research attentions for being a seemingly inexhaustible energy source. For such purpose, solar cells that convert solar energy directly into electrical energy are developed.

Currently, solar cells are often made of single crystalline silicon or poly crystalline silicon, and such devices account for more than 90% of the solar cell market because of having higher photoelectrical conversion efficiency. However, production of these types of solar cells would require high quality silicon wafers, thereby rendering the manufacturing process cost in-effective.

Another type of solar cell is a thin film solar cell, which has a lower manufacturing cost than single crystalline solar cell. The thin film solar cell includes a glass substrate, a transparent electrode, a photoelectric conversion layer and a back electrode. The transparent electrode is formed on the glass substrate. The photoelectric conversion layer is deposited on the transparent electrode by physical deposition such as sputtering. The back electrode is disposed on the photoelectric conversion layer. In order to increase the efficiency of the solar cell, pyramid-like structures or textured structures are formed on the surface of the transparent conductive layer. However, these pyramid-like or textured structures increase the efficiency of the solar cell only marginally for light may directly pass through the photoelectric conversion layer and transmits out of solar cell without being absorbed therein.

Therefore, there exists in this art a need of improved solar cells having higher photoelectric conversion efficiency.

### SUMMARY

The present disclosure provides a solar cell, which includes a substrate, a photoactive member and a two dimensional photonic crystal. The photoactive member is disposed on a surface of the substrate. The two dimensional photonic crystal is disposed on the surface of the substrate and adjacent to the photoactive member such that a light propagated from the photoactive member is reflected back to the photoactive member.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a top view schematically illustrating a solar cell according to one embodiment of the present disclosure;

FIG. 2 is a cross-sectional view schematically illustrating a solar cell according to one embodiment of the present disclosure;

FIG. 3A to FIG. 3C are top views schematically illustrating a two dimensional photonic crystal according to one embodiment of the present disclosure; and

FIG. 4A to FIG. 4C are top views schematically illustrating a two dimensional photonic crystal according to another embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

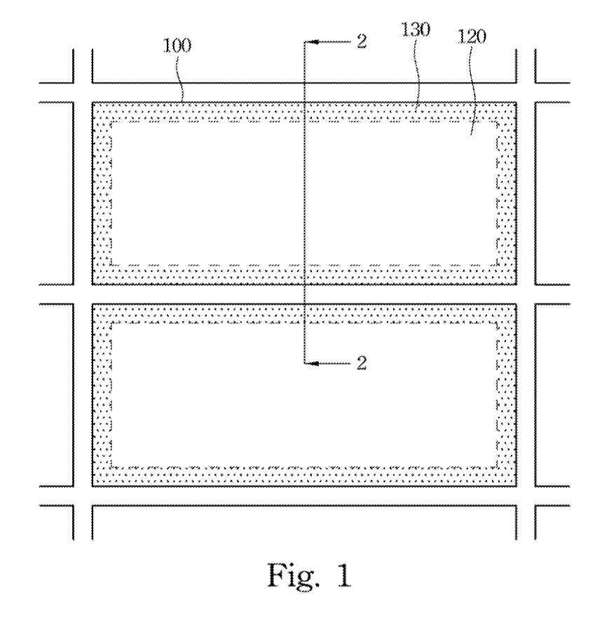

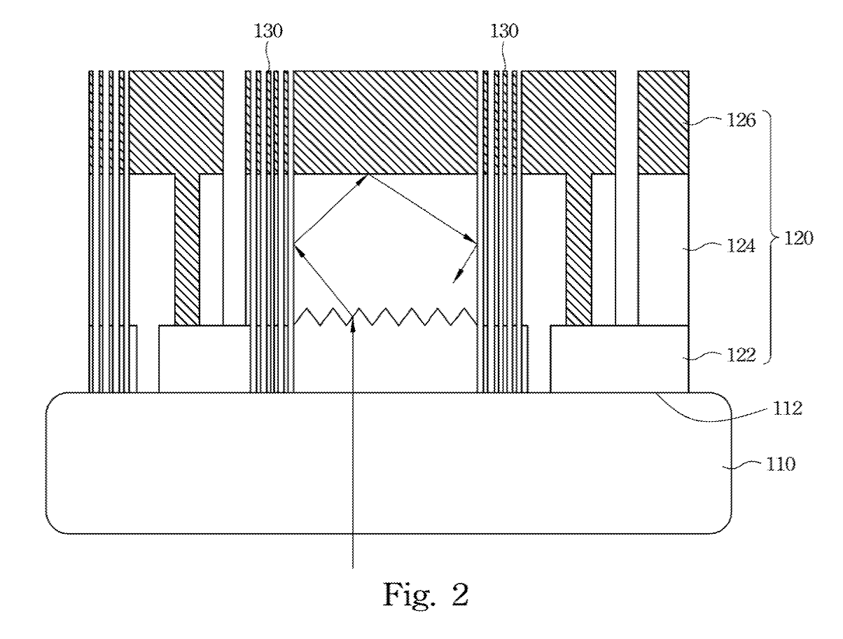

FIG. 1 is a top view schematically illustrating a solar cell 100 according to one embodiment of the present disclosure. FIG. 2 is a cross-sectional view taking along line 2-2 in FIG. 1. Referring to FIG. 1 and FIG. 2, the solar cell 100 includes a substrate 110, a photoactive member 120, and a two dimensional photonic crystal 130.

The substrate 110 has a substantially flat surface 112, on which the photoactive member 120 is disposed. In one embodiment, the substrate 110 is transparent to sunlight for propagating sunlight to the photoactive member 120. For example, the substrate 110 may be made of glass or other transparent plastics such as Poly(methyl methacrylate) (PMMA), polystyrene and polycarbonate. In the case, when the substrate is a transparent glass substrate, the solar cell 100 may receive sunlight from the side of the substrate. In one example, the glass substrate has a thickness of about 3.2 mm to about 6 mm.

The photoactive member 120 is disposed on the surface 112 of the substrate 110, and capable of converting light into electricity. In one embodiment, the photoactive member 120 may be a silicon chip comprising single crystal or polycrystalline silicon. In another embodiment, the photoactive member 120 may be a thin film photovoltaic device, and comprises a transparent conductive layer 122, a photovoltaic layer 124, and a metal layer 126, as illustrated in FIG. 2.

In this embodiment, the transparent conductive layer 122 is disposed on the surface 112. In some examples, the transparent conductive layer 122 is a transparent conductive oxide such as zinc oxide (ZnO), fluorine doped tin dioxide (SnO₂:F), and indium tin oxide (ITO). In other examples, the transparent conductive layer 122 has a textured surface for trapping light that is transmitted into the solar cell 100. The photovoltaic layer 124 is disposed above the transparent conductive layer 122. In one example, the photovoltaic layer 124 comprises amorphous silicon and has a p-i-n structure composed of a p-type semiconductor, an intrinsic semiconductor and a n-type semiconductor (not shown). In other examples, the photovoltaic layer 124 may comprise gallium arsenide (GaAs), copper indium gallium diselenide (CIGS), or cadmium telluride (CdTe). When photovoltaic layer 124 absorbs light, electron-hole pairs are generated therein, and then the electron-hole pairs are separated by the electric field established in the photovoltaic layer 124 to form electric current. The metal layer 126 is disposed on the photovoltaic layer 124, and may also function as a mirror. In some examples, the metal layer 126 may include silver, aluminum, copper, chromium or nickel, depending on the needs. Both the metal layer 126 and the transparent conductive layer 122 are capable of transmitting the electric current generated by the photovoltaic layer 124 to an external loading device (not shown). The metal layer 126 may also reflect light and function as a mirror. When light reaches on the surface of the metal layer 126 through the photovoltaic layer 124, the metal layer 126 may reflect the light back to the photovoltaic layer 124, as depicted in FIG. 2.

The two dimensional photonic crystal 130 is disposed on the surface 112 of the substrate 110 and adjacent to the photoactive member 120 such that a light propagated from the photoactive member 120 is reflected back to the photoactive member 120. In one embodiment, as depicted in FIG. 1 and FIG. 2, the two dimensional photonic crystal 130 surrounds the photoactive member 120 and has a structure periodically repeated on a direction that is parallel with the surface 112. When light propagates into the photovoltaic layer 124, a portion of the light may be absorbed and thus generate electricity. However, a portion of the light may directly pass through the photovoltaic layer 124 without generating electricity. The light that directly passes through the photovoltaic layer 124 can be reflected back by the two dimensional photonic crystal 130 and by the metal layer 126. Therefore, the light that transmits into the photoactive member 120 can be trapped therein and is subsequently converted into electricity. As a result, the efficiency of the solar cell may be dramatically increased.

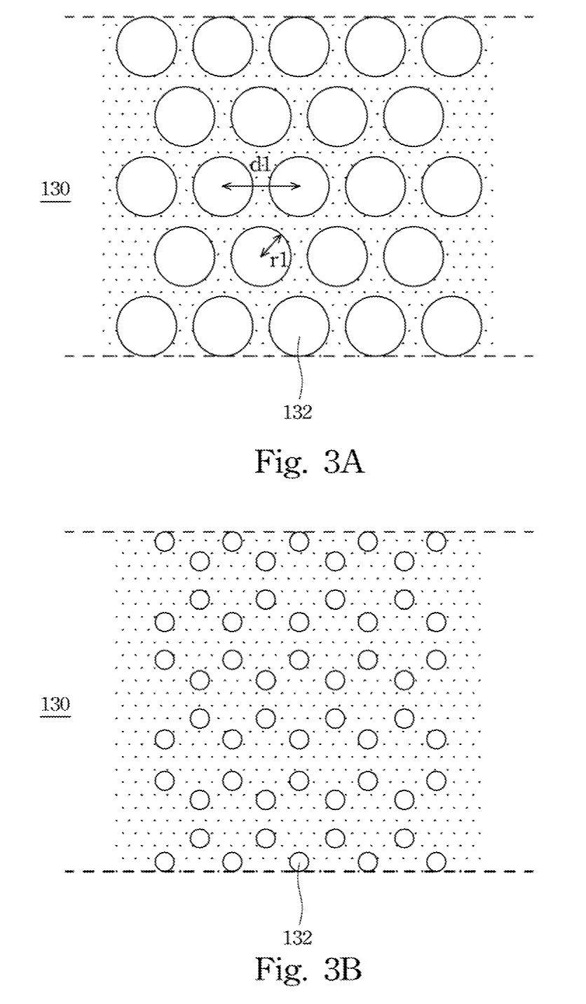

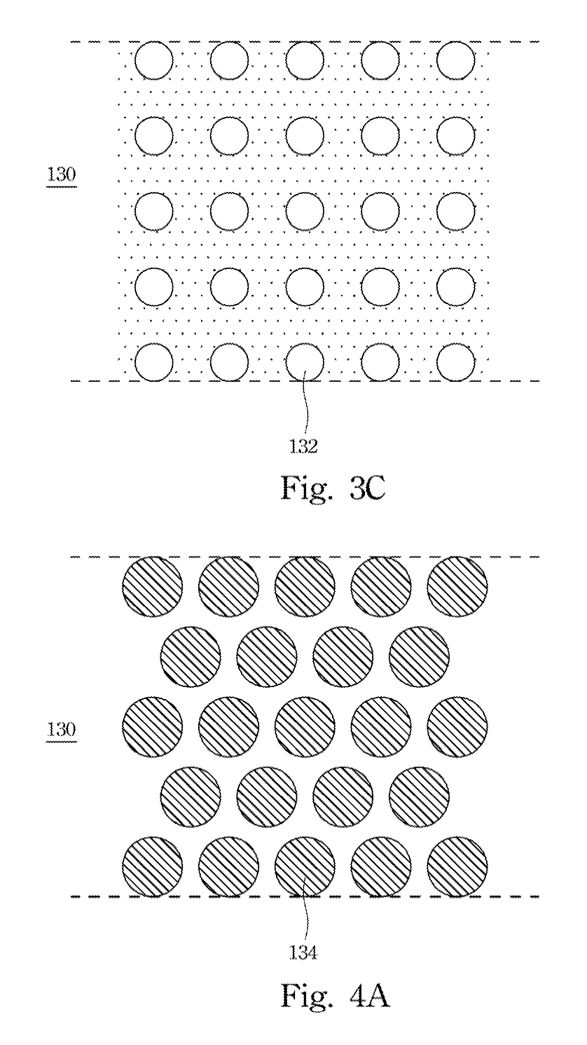

FIG. 3A to FIG. 3C are top views schematically illustrating the arrangement of the two dimensional photonic crystals 130 according to one embodiment of the present disclosure. In this embodiment, the two dimensional photonic crystal 130 may be periodically repeated along a direction that is parallel with the surface 112. For example, there may be at least three repeated layers of the two dimensional photonic crystal 130, including but is not limited to 3, 4, 5, 6, 7, 8, 9 or 10 layers of the two dimensional photonic crystal 130.

In one embodiment, the two dimensional photonic crystal 130 comprises a plurality of air columns 132 formed therein, and each of the air columns 132 is perpendicular to the surface 112 of the substrate 110. In one example, the plurality of air columns 132 are arranged in a triangular lattice pattern, as depicted in FIG. 3A. Each of the air columns 132 has a radius r1 of about 85 nm to about 167 nm, preferably from about 105 nm to about 143 nm; and the distance d1 between the geometric centers of two adjacent air columns 132, may be about 189 nm to about 340 nm, preferably from about 234 nm to about 293 nm. In another example, the plurality of air columns 132 may be arranged in a honeycomb lattice pattern, as depicted in FIG. 3B. In other examples, the plurality of air columns 132 may be arranged in a square lattice pattern, as depicted in FIG. 3C.

In one embodiment, the plurality of air columns 132 penetrates the photoactive member 120 of the solar cell 100. For example, the photoactive member 120 may comprise a transparent conductive layer 122, a photovoltaic layer 124 and a metal layer 126, and then the air columns 132 penetrate all of the transparent conductive layer 122, photovoltaic layer 124 and metal layer 126, as depicted in FIG. 2. The method of forming the air columns 132 is not limited. For example, the photolithography process, electron beam lithography process and/or laser scribing method may be employed to form the air columns 132.

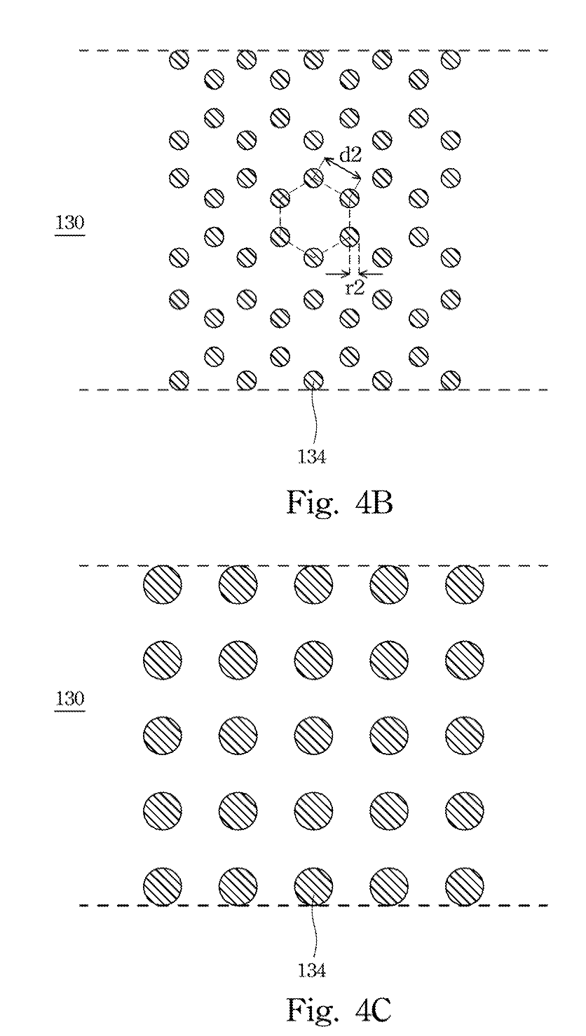

FIG. 4A to FIG. 4C are top views schematically illustrating the two dimensional photonic crystals 130 according to another embodiment of the present disclosure. In this embodiment, the two dimensional photonic crystal 130 comprises a plurality of dielectric columns 134 and each of the dielectric columns 134 is perpendicular to the surface 112. In one example, the plurality of dielectric columns 134 are arranged in a triangular lattice pattern, as depicted in FIG. 4A. In another example, the plurality of dielectric columns 134 are arranged in a honeycomb lattice pattern. Each of the dielectric columns 134 has a radius r2 of about 74 nm to about 92 nm, and the distance between the geometric centers of the two adjacent dielectric columns 134 is about 307 nm to about 336 nm, as depicted in FIG. 4B. In other examples, the plurality of dielectric columns 134 are arranged in a square lattice pattern, as depicted in FIG. 4C.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A solar cell, comprising:
a substrate having a surface;
a photoactive member disposed on the surface of the substrate; and
a two dimensional photonic crystal disposed on the surface of the substrate and adjacent to the photoactive member such that a light propagated from the photoactive member is reflected back to the photoactive member.

2. The solar cell according to claim 1, wherein the two dimensional photonic crystal has a structure periodically repeated on a direction that is parallel with the surface.

3. The solar cell according to claim 2, wherein the two dimensional photonic crystal comprises a plurality of air columns formed therein, and wherein each of the air columns is perpendicular to the surface.

4. The solar cell according to claim 3, wherein the plurality of air columns are arranged in a triangular lattice pattern.

5. The solar cell according to claim 4, wherein each of the air columns has a radius of about 105 nm to about 143 nm.

6. The solar cell according to claim 5, wherein a distance between the geometric centers of two adjacent air columns is about 234 nm to about 293 nm.

7. The solar cell according to claim 3, wherein the plurality of air columns are arranged in a honeycomb lattice pattern.

8. The solar cell according to claim 3, wherein the plurality of air columns are arranged in a square lattice pattern.

9. The solar cell according to claim 3, wherein the photoactive member comprises:
a transparent conductive layer disposed on the surface;
a photovoltaic layer disposed above the transparent conductive layer; and
a metal layer disposed above the photovoltaic layer.

10. The solar cell according to claim 9, wherein the plurality of air columns penetrates the transparent conductive layer, the photovoltaic layer and the metal layer.

11. The solar cell according to claim 2, wherein the two dimensional photonic crystal comprises a plurality of dielectric columns and each of the dielectric columns is perpendicular to the surface.

12. The solar cell according to claim 11, wherein the plurality of dielectric columns are arranged in a triangular lattice pattern.

13. The solar cell according to claim 11, wherein the plurality of dielectric columns are arranged in a honeycomb lattice pattern.

14. The solar cell according to claim 13, wherein each of the dielectric columns has a radius of about 74 nm to about 92 nm.

15. The solar cell according to claim 14, wherein a distance between the geometric centers of the two adjacent dielectric columns is about 307 nm to about 336 nm.

16. The solar cell according to claim 11, wherein the plurality of dielectric columns are arranged in a square lattice pattern.

17. The solar cell according to claim 1, wherein the two dimensional photonic crystal surrounds the photoactive member.
